(19) United States
(12) Patent Application Publication
(10) Pub. No.: US 2023/0408584 A1
(43) Pub. Date: Dec. 21, 2023

(54) ELECTROCHEMICAL MODEL BASED METHOD FOR EARLY WARNING FOR LITHIUM BATTERIES

(71) Applicant: SHANGHAI MAKESENS ENERGY STORAGE TECHNOLOGY CO., LTD., Shanghai (CN)

(72) Inventors: Danfei Gu, Shanghai (CN); Mingchen Jiang, Shanghai (CN); Siyuan Chen, Shanghai (CN); Xiao Yan, Shanghai (CN); Enhai Zhao, Shanghai (CN); Peng Ding, Shanghai (CN); Pei Song, Shanghai (CN); Weikun Wu, Shanghai (CN); Xiaohua Chen, Shanghai (CN)

(21) Appl. No.: 18/206,669

(22) Filed: Jun. 7, 2023

(30) Foreign Application Priority Data
Jun. 17, 2022 (CN) 202210688445.8

(51) Int. Cl. G01R 31/367; G01R 31/378

(52) U.S. Cl. CPC G01R 31/367; G01R 31/378

(57) ABSTRACT

The invention provides an electrochemical model based method for early warning for a lithium battery, including establishing a three-dimensional electrochemical model for the lithium battery, and dividing the lithium battery into three portions respectively including a positive electrode, a negative electrode and a separator; performing spatial discretization on the three-dimensional electrochemical model according to a preset accuracy to establish the four-dimensional spatial coordinates of the lithium battery; obtaining a current lithium ion concentration in each position of the lithium battery by simulation based on the four-dimensional space coordinates, a historical lithium ion concentration and a historical diffusion coefficient of the lithium battery; and performing early warning for the lithium battery according to the current lithium ion concentration in each position. The method adopts the volumetric SOC or surface SOC of the lithium battery for operation management, which is direct and objective, and can be is applied to most external environments.

### CROSS-REFERENCE TO RELATED PATENT APPLICATION

This application claims priority to and the benefit of Chinese Patent Application No. 202210688445.8, filed Jun. 17, 2022, which are incorporated herein in their entireties by reference.

### FIELD OF THE INVENTION

The invention relates generally the field of batteries, and more particularly to an electrochemical model based method for early warning for lithium batteries.

### BACKGROUND OF THE INVENTION

In the context of global “carbon neutral”, the search for clean energy that can replace petroleum energy continues to heat up. Solar energy, tidal energy, wind energy, water energy, etc. are clean and sustainable energy sources, but the controllability of media that generate energy is relatively not very strong. Lithium batteries are currently a new generation of batteries, which have high energy density and long cycle life, and are widely used in mobile communications, digital technology, electric vehicles, energy storage and other fields. The demand for lithium batteries and materials thereof in the future is incalculable, and the corresponding upstream and downstream industrial chains have a huge market. By establishing a physical and chemical model for the lithium battery, and obtaining the simulation numerical values of the physical and chemical state quantities in the space and time inside the lithium battery, the real-time working state of the lithium battery can be clearly known and monitored, so that the economy, reliability and safety of the lithium battery are better guaranteed.

In the electrochemical model, the transformation of most physicochemical state quantity fields with time and space is described by time-domain partial differential equations. On one hand, these partial differential equations are described in both time and space, and attention needs to be paid to space-time separation. On the other hand, multiple partial differential equations are strongly coupled to each other, and decoupling is needed when numerical simulation is performed. In the electrochemical pseudo-two-dimensional coupling model, its equation describes only one dimension in the Euclidean space, and meanwhile, the radius dimension of particles at the position is wound everywhere in one-dimensional Euclidean space. In the two spatial dimensions of the electrochemical pseudo-two-dimensional coupling model, electric fields, thermal fields, stress fields and other multi-fields are coupled, so that various physical and chemical processes such as electrochemistry, mass transfer, heat transfer, momentum transfer and the like are represented, and particles, solid, liquid, metal, is macromolecules and other phases and sub-phases are included, and the coupling model is very complex. At present, the simulation of electrochemical models is mostly based on computing software such as ansys, comsol and fluent, and there are very few electrochemical models built by themselves based on the principle of numerical simulation.

In the field of early warning and diagnosis of batteries, most diagnostic early warnings are based on threshold judgment or comprehensive judgment based on the macroscopic state of the battery. Specifically, the judgment and monitoring of the battery state are performed using the macroscopic voltage of the battery or some parameters simply calculated from the macroscopic voltage. This method is intuitive, efficient and easy to monitor, but it has the following defects: 1. the method is not intrinsic, and cannot accurately represent the real internal state of the battery; 2. lack of some predictability; 3. It cannot adapt to the environment in which the battery is located.

Therefore, a heretofore unaddressed need exists in the art to address the aforementioned deficiencies and inadequacies.

### SUMMARY OF THE INVENTION

In view of the above-noted shortcomings, one of the objectives of this invention is to provide an early warning method for lithium batteries based on an electrochemical model, which is used to solve the problems that the existing battery early warning method is not intrinsic and lacks certain predictability for the battery state.

In one aspect of the invention, the method includes establishing a three-dimensional (3D) electrochemical model for the lithium battery, and dividing the lithium battery into three portions respectively including a positive electrode, a negative electrode and a separator; performing spatial discretization on the 3D electrochemical model according to a preset accuracy to establish the four-dimensional (4D) spatial coordinates of the lithium battery; obtaining a current lithium ion concentration in each position of the lithium battery by simulation based on the 4D space coordinates, a historical lithium ion concentration and a historical diffusion coefficient of the lithium battery; and performing early warning for the lithium battery according to the current lithium ion concentration in each position.

In one embodiment, said obtaining the current lithium ion concentration in each position of the lithium battery by simulation based on the 4D space coordinates, the historical lithium ion concentration and the historical diffusion coefficient in each position of the lithium battery comprises loading the solid-phase lithium ion concentration obtained by electric field decoupling at the immediately previous moment; and based on a solid-phase lithium ion concentration governing equation, obtaining the solid-phase lithium ion concentration at the immediately next moment by a finite difference analysis. The solid-phase lithium ion concentration governing equation comprises:

$$\frac{\partial {c}_{s}}{\partial t} ( x , y , z , r , t ) = \frac{1}{{r}^{2}} \frac{\partial }{\partial r} [ {D}_{s}^{\pm } {r}^{2} \frac{\partial {c}_{s}}{\partial r} ]$$

wherein Cₛ is the solid-phase lithium ion concentration, x, y, z are the 3D space coordinates, r is the radius dimension of x, y, z winding; t is time;

$${D}_{s}^{\pm }$$

is a solid-phase mass transfer coefficient.

In one embodiment, the solid-phase lithium ion concentration governing equation further comprises letting ζ=Cₛ·r, and changing

$$\frac{\partial {c}_{s}}{\partial t} ( x , y , z , r , t ) = \frac{1}{{r}^{2}} \frac{\partial }{\partial r} [ {D}_{s}^{\pm } {r}^{2} \frac{\partial {c}_{s}}{\partial r} ]$$

to:

$$\frac{\partial ζ}{\partial t} ( x , y , z , r , t ) = {D}_{s}^{\pm } \frac{\partial }{\partial r} [ \frac{\partial ζ}{\partial r} ] .$$

In one embodiment, said obtaining the current lithium ion concentration in each position of the lithium battery by simulation based on the 4D space coordinates, the historical lithium ion concentration and the historical diffusion is coefficient in each position of the lithium battery comprises loading the liquid phase lithium ion concentration obtained by electric field decoupling at the immediately previous moment; and based on an liquid phase lithium ion concentration governing equation, obtaining a liquid phase lithium ion concentration at the immediately next moment by a finite element method analysis. The liquid-phase lithium ion concentration governing equation is:

$${ε}_{e}^{j} \frac{\partial {c}_{e}^{j}}{\partial t} ( x , y , z , t ) = {D}_{e} Δ {c}_{e}^{j} + {a}^{\pm } ( 1 - t ) {j}_{n}^{\pm } ( x , t )$$

wherein j represents the positive electrode, the negative electrode or the separator, Cₑ is the lithium ion concentration in the liquid phase, Dₑ is the mass transfer coefficient in the liquid phase, x, y, z are the 3D spatial coordinates, and t is the time.

In one embodiment, said performing early warning for the lithium battery according to the current lithium ion concentration in each position comprises calculating state information of the lithium battery according to the current lithium ion concentration in each position, wherein the state information of the lithium battery includes one or more of a battery volumetric charge state, a battery surface charge state, an active particle volumetric charge state, and an active particle surface charge state; and based on the state information of the lithium battery, determining if operation of the lithium battery is cut off.

Said calculating the battery volumetric charge state includes

$$Bulk {SOC}^{\pm } = \frac{3}{{{L}^{\pm } ( {R}_{p}^{\pm } )}^{3}} {\int }_{0}^{{L}^{\pm }} {\int }_{0}^{{R}_{p}^{\pm }} {r}^{2} \frac{{c}^{\pm }}{{c}_{max}^{\pm }} dr dx$$

wherein Bulk SOC^{±} is the battery volumetric charge state, L^{±} is a length of the positive electrode or the negative electrode,

$${R}_{p}^{\pm }$$

is a particle surface radius of an active material of the positive electrode or the negative electrode, r is a radius in a is particle radius domain of the active material, c is a lithium ion concentration corresponding to a certain radius r in active material particles at a certain position of the x-axis, c^{±} is the lithium ion concentration on the surface of the active material particles at a certain position of the x-axis, and

$${c}_{max}^{\pm }$$

is a maximum volumetric lithium ion concentration that the active material particles can carry.

Said calculating the battery surface charge state includes

$$Surface {SOC}^{\pm } = \frac{1}{{L}^{\pm }} {\int }_{0}^{{L}^{\pm }} \frac{{c}_{ss}^{\pm }}{{c}_{max}^{\pm }} dx$$

wherein Surface SOC^{±} is the battery surface charge state.

Said calculating the active particle volumetric charge state is

$$Particle {SOC}^{\pm } = \frac{3}{{( {R}_{p}^{\pm } )}^{3}} {\int }_{0}^{{R}_{p}^{\pm }} {r}^{2} \frac{{c}^{\pm }}{{c}_{max}^{\pm }} dr$$

wherein Particle SOC^{±} is the active particle volumetric charge state.

Said calculating the active particle surface charge state is

$$Particle Surface {SOC}^{\pm } = \frac{{c}_{ss}^{\pm }}{{c}_{max}^{\pm }} .$$

In one embodiment, based on the state information of the lithium battery, said determining if operation of the lithium battery is cut off comprises when the battery volume charge state is between a first threshold and a second threshold, cutting off the operation of the lithium battery.

In one embodiment, based on the state information of the lithium battery, said determining if operation of the lithium battery is cut off comprises when the battery surface charge state is between a third threshold and a fourth threshold, cutting off the operation of the lithium battery.

In one embodiment, based on the state information of the lithium battery, said determining if operation of the lithium battery is cut off comprises when the is active particle volume charge state of the solid particles of the lithium battery exceeding a fifth threshold exceeds a first preset range, cutting off the operation of the lithium battery.

In one embodiment, based on the state information of the lithium battery, said determining if operation of the lithium battery is cut off comprises when the active particle volume charge state of the solid particles of the lithium battery exceeding a sixth threshold exceeds a second preset range, cutting off the operation of the lithium battery.

Compared with the prior art, the electrochemical model based method for early warning for the lithium battery of the invention provides the beneficial effects, as follows.

1. The invention provides a numerical simulation method for lithium ion concentrations of electrodes and electrolyte of the lithium battery based on an electrochemical model with both time efficiency and spatial efficiency.

2. The invention provides a basis for the new type of battery operation management, which is objective and effective, and has more practical scenarios.

3. The invention provides a basis for establishing a digital twin system of a lithium battery-a lithium battery model component based on a deductive method

### BRIEF DESCRIPTION OF THE DRAWINGS

The accompanying drawings illustrate one or more embodiments of the invention and, together with the written description, serve to explain the principles of the invention. The same reference numbers may be used throughout the drawings to refer to the same or like elements in the embodiments.

FIG. 1 shows schematically a flowchart of an electrochemical model based method for early warning for a lithium battery according to one embodiment of the invention.

FIG. 2 shows the lithium ion concentration at various locations on the solid phase surface at a particular time in a lithium battery according to one embodiment of the invention.

FIG. 3 is a graph of the concentration of lithium ions in the electrolyte at various points in a lithium battery according to one embodiment of the invention.

FIG. 4 is a radial lithium ion concentration of solid phase active material particles at a point in time in a lithium battery according to one embodiment of the invention.

FIG. 5 shows schematically a flowchart of an electrochemical model based method for early warning for a lithium battery according to one embodiment of the invention.

### DETAILED DESCRIPTION OF THE INVENTION

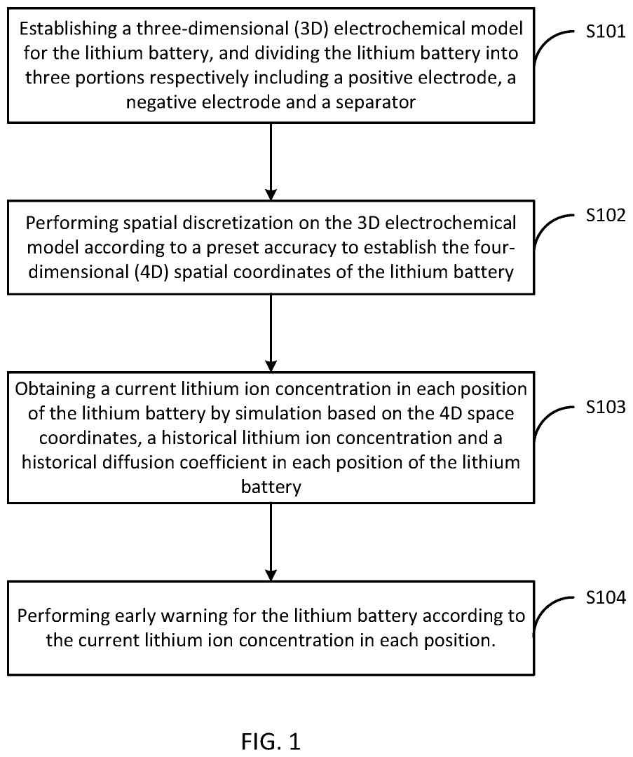

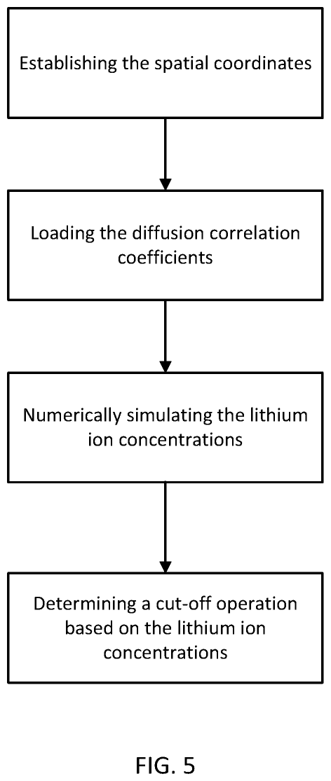

Embodiments of the invention are described below through specific examples in conjunction with the accompanying drawings in FIGS. 1-5, and those skilled in the art can easily understand other advantages and effects of the invention from the content disclosed in this specification. The invention can also be implemented or applied through other different specific implementations, and various modifications or changes can be made to the details in this specification based on different viewpoints and applications without departing from the spirit of the invention. It should be noted that, in the case of no conflict, the following embodiments and features in the embodiments can be combined with each other.

It should be noted that the drawings provided in the following embodiments are merely illustrative in nature and serve to explain the principles of the invention, and are in no way intended to limit the invention, its application, or uses. Only the components related to the invention are shown in the drawings rather than the number, shape and size of the components in actual implementations. For components with the same structure or function in some figures, only one of them is schematically shown, or only one of them is marked. They do not represent the actual structure of the product. Dimensional drawing, the type, quantity and proportion of each component can be changed arbitrarily in its actual implementations. More complicate component layouts may also become apparent in view of the drawings, the specification, and the following claims.

The terminology used herein is for the purpose of describing particular embodiments only and is not intended to be limiting of the invention. As used herein, “a” not only means “only one”, but also means “more than one”. The term “and/or” used in the description of the present application and the appended claims refers to any combination and all possible combinations of one or more of the associated listed items, and includes these combinations. The terms “first”, “second”, etc. are only used for distinguishing descriptions, and should not be construed as indicating or implying relative importance.

As shown in FIG. 1, a flowchart of an electrochemical model based method for early warning for a lithium battery is shown schematically according to one embodiment of the invention. The method includes the following steps.

As step S101, establishing a three-dimensional (3D) electrochemical model for the lithium battery, and dividing the lithium battery into three portions respectively including a positive electrode, a negative electrode and a separator.

Specifically, the invention provides an electrochemical model-based method for numerical simulation and operation management of the lithium ion concentrations in the lithium battery electrodes and electrolytes.

For a pseudo-two-dimensional electrochemical model reported in literature, although it can describe the situation of the battery very well, it oversimplifies the is spatial dimension of the battery, causing it to ignore the high-dimensional dimension effect and edge size effect, which may lead to inaccuracies.

According to the invention, a 3D model is established in proportion to the actual scale of the lithium battery, where the lithium battery can be roughly divided into three portions including a positive electrode, a negative electrode and a separator.

Exemplary electrochemical models include, but are not limited to, pseudo-two-dimensional (P2D) model, P2D thermal coupling model, single particle model (SPM), single particle model with electrolyte (SPMe), various extended single particle models (SP+model), etc.

At step S102, performing spatial discretization on the 3D electrochemical model according to a preset accuracy to establish the four-dimensional (4D) spatial coordinates of the lithium battery.

Firstly, the spatial 3D electrochemical model is discretized according to the preset accuracy to obtain the discretized 3D electrochemical model, which includes obtaining the physical size of the lithium battery; and based on the physical size of the lithium battery, establishing the 3D electrochemical model of the lithium battery according to the preset ratio.

Specifically, a solid-phase electrode particle ball is mapped proportionally to the sizes of the electrodes and the sizes of the solid-phase electrode particle at each position in the spatial 3D electrochemical model, so there are 4D coordinates.

Exemplarily, after the spatial 3D electrochemical model is established, the 3D model is spatially discretized according to the requirement of accuracy.

It is easy to understand that the smaller the discrete interval, the better the numerical simulation, but there is a trade-off between efficiency and accuracy. A better approach is to have denser discreteness at the some edge portions, and thinner discreteness in the middle portions; and denser discreteness at large is curvatures of twists and turns, and thinner discreteness at the flat portions. A better choice when the spatial curvatures are uniform is the Chebyshev point. Then, a small ball proportional to the actual size of the solid phase particles of the electrode is wound at each node. The spherical shell is discretized radially on the sphere, and the proposal for discretization of the R axis is according to the Chebyshev point.

At step S103, obtaining a current lithium ion concentration in each position of the lithium battery by simulation based on the 4D space coordinates, a historical lithium ion concentration and a historical diffusion coefficient in each position of the lithium battery.

Specifically, a diffusion coefficient is loaded, then, based on the common numerical methods and each position of the 4D space and the diffusion governing equation in the previous second, each position of the 4D space and the diffusion governing equation in the next second is calculated. Finally, early warning diagnosis is performed based on the obtained lithium ion concentrations.

In one embodiment, the diffusion coefficient includes a diffusion coefficient identified according to big data parameters, and/or a diffusion coefficient determined through historical data and derived from temperature changes and thermal coupling.

Exemplarily, the diffusion coefficient can be identified through the big data parameters, or can be determined experimentally and derived by the temperature transformation and thermal coupling to obtain a value of the parameter in that state, or may be derived by other models. These three components actually constitute the majority of the sources of parameters for the practical applications of the invention.

It is easy to understand that these diffusion coefficients must be time-efficient, i.e., they can more accurately reflect the current state of lithium battery-related processes.

At step S104, performing early warning for the lithium battery according to the current lithium ion concentration in each position.

In one embodiment, a 3D spatial model is established firstly, and a solid-phase electrode particle ball is mapped proportionally to the sizes of the electrodes and the sizes of the solid-phase electrode particle at each position in the spatial 3D electrochemical model, so there are 4D coordinates.

Secondly, the diffusion coefficient is loaded, then, based on the common numerical methods and each position of the 4D space and the diffusion governing equation in the previous second, each position of the 4D space and the diffusion governing equation in the next second is calculated. Finally, early warning diagnosis is performed based on the obtained lithium ion concentrations.

In one embodiment, said obtaining the current lithium ion concentration in each position of the lithium battery by simulation based on the 4D space coordinates, the historical lithium ion concentration and the historical diffusion coefficient in each position of the lithium battery comprises loading the solid-phase lithium ion concentration obtained by electric field decoupling at the immediately previous moment; and based on a solid-phase lithium ion concentration governing equation, obtaining the solid-phase lithium ion concentration at the immediately next moment by a finite difference analysis. The solid-phase lithium ion concentration governing equation comprises:

$$\frac{\partial {c}_{s}}{\partial t} ( x , y , z , r , t ) = \frac{1}{{r}^{2}} \frac{\partial }{\partial r} [ {D}_{s}^{\pm } {r}^{2} \frac{\partial {c}_{s}}{\partial r} ]$$

wherein Cₛ is the solid-phase lithium ion concentration, x, y, z are the 3D space coordinates, r is the radius dimension of x, y, z winding; t is time;

$${D}_{s}^{\pm }$$

is a solid-phase mass transfer coefficient.

Specifically, in the step of the numerical simulation of the lithium ion concentrations, the solid-liquid exchange lithium ion concentration jn at each is position of a certain moment/time obtained by electric field decoupling is loaded first, and the solid-phase lithium ion concentration governing equation is then used to solve the solid-phase lithium ion concentration at the next moment/time.

In one embodiment, said obtaining a current lithium ion concentration in each position of the lithium battery by simulation further comprises letting ζ=Cₛ·r, and rewriting

$$\frac{\partial {c}_{s}}{\partial t} ( x , y , z , r , t ) = \frac{1}{{r}^{2}} \frac{\partial }{\partial r} [ {D}_{s}^{\pm } {r}^{2} \frac{\partial {c}_{s}}{\partial r} ]$$

to:

$$\frac{\partial ζ}{\partial t} ( x , y , z , r , t ) = {D}_{s}^{\pm } \frac{\partial }{\partial r} [ \frac{\partial ζ}{\partial r} ] .$$

Preferably, there is actually a skill for this equation is to set ζ=Cₛ·r to rewrite the partial differential equation (PDE), with its initial value Cₛ at each position at the previous moment. As an example, only the calculation between two moments is involved.

Assume that at time t₀, the solid phase concentration at each position inside the sphere at x is:

Cₛ(x,0,t₀),Cₛ(x,r₁,t₀),Cₛ(x,r₂,t₀),Cₛ(x,R,t₀).

If the time t₀+Δt is required, the solid phase concentration at each position can be approximated with the partial differential by using the difference according to the PDE, and the differential algebraic equations can be established accordingly.

The solid phase concentration on each discrete point of the small ball can be obtained by solving the difference equation set, which is the idea of a more simple finite difference method. The numerical simulation can be carried out by adopting more advanced finite volume, finite element, spectral method and other methods to on the numerical method.

In one embodiment, said obtaining the current lithium ion concentration in each position of the lithium battery by simulation based on the 4D space coordinates, the historical lithium ion concentration and the historical diffusion coefficient in each position of the lithium battery comprises loading the liquid is phase lithium ion concentration obtained by electric field decoupling at the immediately previous moment; and based on an liquid phase lithium ion concentration governing equation, obtaining a liquid phase lithium ion concentration at the immediately next moment by a finite element method analysis. The liquid-phase lithium ion concentration governing equation is:

$${ε}_{e}^{j} \frac{\partial {c}_{e}^{j}}{\partial t} ( x , y , z , t ) = {D}_{e} Δ {c}_{e}^{j} + {a}^{\pm } ( 1 - t ) {j}_{n}^{\pm } ( x , t )$$

wherein j represents the positive electrode, the negative electrode or the separator, Cₑ is the lithium ion concentration in the liquid phase, Dₑ is the mass transfer coefficient in the liquid phase, x, y, z are the 3D spatial coordinates, and t is the time.

Specifically, the superscript j represents the positive electrode, the negative electrode or the separator. The liquid phase lithium ion concentrations in the three regions is calculated separately. x, y, z, t are the spatial and time coordinates.

In one embodiment, since the dimension is 3D, the finite volume method or finite element method is preferable, compared to the finite difference method. The difference between them and some difference methods is that the finite difference method is to construct algebraic equations for discrete points, while the finite volume method is for discrete volumes, and the average value of several feature points in the volume is used as the physical and chemical properties of the volume. Quantities are used to construct algebraic equations; finite element is based on variation and weighted integrals to transform the desired physical quantity function into a series of base functions and construct algebraic equations on discrete elements.

After the above equations are constructed, it is necessary to substitute the lithium ion concentration and diffusion correlation coefficient at each position at the previous moment and the solid-liquid exchange lithium ion concentration is obtained by electric field decoupling to obtain the lithium ion concentration at each position at the next moment. This equation uses FVM, and FEM to establish algebraic equations between points in space that satisfy this equation.

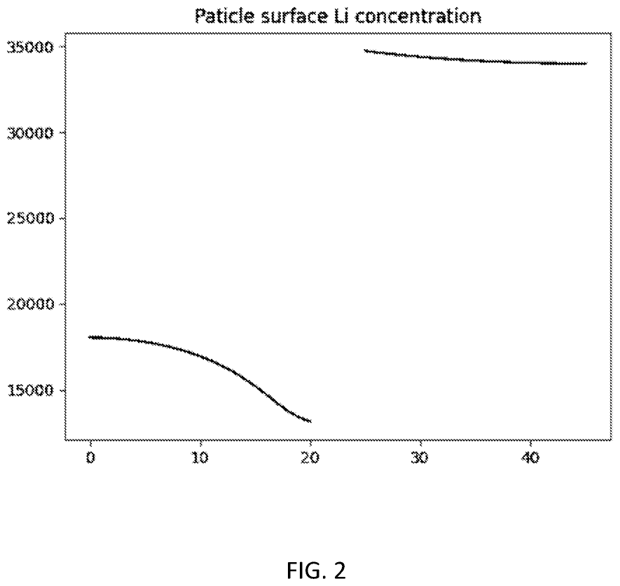

In some embodiments, as shown in FIGS. 2-4, said performing early warning for the lithium battery according to the current lithium ion concentration in each position comprises calculating state information of the lithium battery according to the current lithium ion concentration in each position, wherein the state information of the lithium battery includes one or more of a battery volumetric charge state, a battery surface charge state, an active particle volumetric charge state, and an active particle surface charge state.

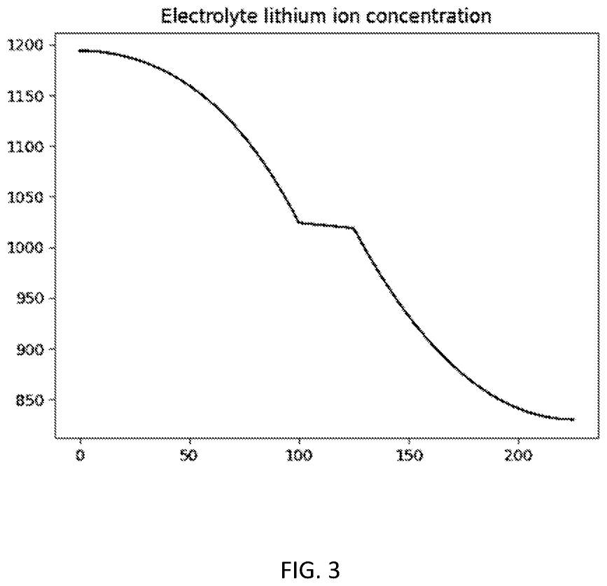

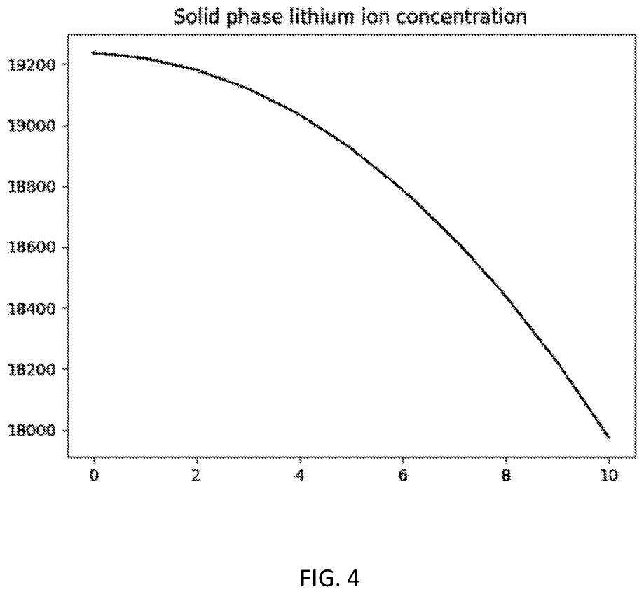

Specifically, FIG. 2 shows the lithium ion concentrations on the solid phase surface of a lithium battery at each position at a certain moment. FIG. 3 shows the lithium ion concentrations in the electrolyte of a lithium battery at each position at a certain moment. FIG. 4 shows the radial lithium ion concentration of solid-phase active material particles at a certain position at a certain moment in a lithium battery.

In the current battery operation management, whether the battery can continue to operate is generally determined according to whether the macroscopic voltage reaches a cut-off voltage. For example, the working range of a common lithium battery is 3.2V-3.7V, which is based on voltage management: the lithium battery is cut off at 3.2V discharge and 3.7V charge. However, this method is obviously extremely subjective, lacks timeliness, and in most cases is too conservative (to avoid risks). For example, it is obviously problematic to mechanically use 3.2-3.7V for any external environment (temperature, charge and discharge rate, humidity, etc.

The invention adopts the volumetric SOC or surface SOC of the solid-phase lithium ion battery for operation management. This management method is direct is and objective, and can be applied to most external environments.

In one embodiment, said calculating the battery volumetric charge state includes

$$Bulk {SOC}^{\pm } = \frac{3}{{{L}^{\pm } ( {R}_{p}^{\pm } )}^{3}} {\int }_{0}^{{L}^{\pm }} {\int }_{0}^{{R}_{p}^{\pm }} {r}^{2} \frac{{c}^{\pm }}{{c}_{max}^{\pm }} dr dx$$

wherein Bulk SOC^{±} is the battery volumetric charge state, i.e., the volumetric state of charge of the lithium battery, or the state of charge of the whole body/volume of the lithium battery, superscript “+” and “−” respectively represent the positive electrode and the negative electrode, L^{±} is a length of the positive electrode or the negative electrode,

$${R}_{p}^{\pm }$$

is a particle surface radius of an active material of the positive electrode or the negative electrode, r is a radius in a particle radius domain of the active material, c is a lithium ion concentration corresponding to a certain radius r in active material particles at a certain position of the x-axis, C^{±} is the lithium ion concentration on the surface of the active material particles at a certain position of the x-axis, and

$${c}_{max}^{\pm }$$

is a maximum volumetric lithium ion concentration that the active material particles can carry.

In one embodiment, said calculating the battery surface charge state includes

$$Surface {SOC}^{\pm } = \frac{1}{{L}^{\pm }} {\int }_{0}^{{L}^{\pm }} \frac{{c}_{ss}^{\pm }}{{c}_{max}^{\pm }} dx$$

wherein Surface SOC^{±} is the battery surface charge state, i.e., the surface state of charge of the lithium battery, or the state of charge on the surface of the lithium battery, and

$${c}_{ss}^{\pm }$$

is the solid surface concentration.

In one embodiment, said calculating the active particle volumetric charge state is

$$Particle {SOC}^{\pm } = \frac{3}{{( {R}_{p}^{\pm } )}^{3}} {\int }_{0}^{{R}_{p}^{\pm }} {r}^{2} \frac{{c}^{\pm }}{{c}_{max}^{\pm }} dr$$

wherein Particle SOC^{±} is the active particle volumetric charge state, i.e., the volumetric state of charge of the active particles, or the state of charge in the is bodies of the active particles.

In one embodiment, said calculating the active particle surface charge state is

$$Particle Surface {SOC}^{\pm } = \frac{{c}_{ss}^{\pm }}{{c}_{max}^{\pm }} .$$

wherein Particle Surface SOC^{±} is the active particle surface charge state, i.e., the surface state of charge of the active particles, or the state of charge on the active particle surfaces, or the state of charge on the surfaces of the active particles.

Specifically, said determining if operation of the lithium battery is cut off, based on the state information of the lithium battery, can be performed by the above state information.

In one embodiment, based on the state information of the lithium battery, said determining if operation of the lithium battery is cut off comprises when the battery volume charge state is between a first threshold and a second threshold, cutting off the operation of the lithium battery.

In one embodiment, based on the state information of the lithium battery, said determining if operation of the lithium battery is cut off comprises when the battery surface charge state is between a third threshold and a fourth threshold, cutting off the operation of the lithium battery.

Specifically, in actual operations, the operation cut-off determination may be that the Bulk SOC is between the first threshold and the second threshold; the Surface SOC is between the third threshold and the fourth threshold.

For example, when the Bulk SOC is between the first threshold and the second threshold, the battery stops working; when the Surface SOC is between the third threshold and the fourth threshold, the battery stops working. That the battery stops working means that the battery stops charging or discharging.

In one embodiment, based on the state information of the lithium battery, said determining if operation of the lithium battery is cut off comprises when the active particle volume charge state of the solid particles of the lithium battery exceeding a fifth threshold exceeds a first preset range, cutting off the operation of the lithium battery.

In one embodiment, based on the state information of the lithium battery, said determining if operation of the lithium battery is cut off comprises when the active particle volume charge state of the solid particles of the lithium battery exceeding a sixth threshold exceeds a second preset range, cutting off the operation of the lithium battery.

In one embodiment, the first to sixth thresholds are 15%, 85%, 5%, 90%, and 90%, respectively. The first and second preset ranges are 85% and 85%, respectively.

It should be noted that these thresholds may or may not be equal, and actually represent different physical meanings. The determination of the specific thresholds is determined by the maximum and minimum volumetric lithium ion concentrations of the battery or material that can carry..

Specifically, it may be more preferred that the solid particles exceeding the fifth threshold:

$$Particle {SOC}^{\pm } = \frac{3}{{( {R}_{p}^{\pm } )}^{3}} {\int }_{0}^{{R}_{p}^{\pm }} {r}^{2} \frac{{c}^{\pm }}{{c}_{max}^{\pm }} dr ,$$

exceeds the sixth or seventh threshold.

Or the solid particles of the eighth threshold:

$$Particle Surface {SOC}^{\pm } = \frac{{c}_{ss}^{\pm }}{{c}_{max}^{\pm }} .$$

exceeds the ninth threshold to the tenth threshold.

Specifically, there are maximum and minimum loads in the lattice of battery active materials, and if the load is outside this range, problems such as lattice is collapse will occur in the active material.

In one embodiment, the present invention provides a numerical simulation method for lithium battery electrodes and electrolyte lithium ion concentration based on an electrochemical model with both time efficiency and spatial efficiency.

At the same time, it also provides a new type of battery work management basis, which is objective and effective, and has more practical scenarios. The invention provides a basis for establishing a lithium battery digital twin system: a lithium battery model component based on deductive method.

In one embodiment, the present invention provides a kind of early warning method of the lithium battery based on electrochemical model, comprises:

In S1, establishing the spatial coordinates.

In S2, loading the diffusion correlation coefficients.

In S3, numerically simulating the lithium ion concentrations in the liquid phase and the solid phase.

In S4, determining a cut-off operation based on the lithium ion concentrations.

The invention provides a method for numerical simulation and operation management of lithium battery electrodes and electrolyte lithium ion concentrations based on the electrochemical models. Firstly, a 3D spatial model is established, and a solid-phase electrode particle ball is mapped proportionally according to the size of the electrode and the particle size of the solid-phase electrode at each position of the space, so there are four-dimensional coordinates. Secondly, based on the common numerical methods and each position of the 4D space and the diffusion governing equation in the previous second, each position of is the 4D space and the diffusion governing equation in the next second is calculated. Finally, an early warning diagnosis is performed based on the obtained lithium ion concentration.

The invention adopts the volumetric SOC or surface SOC of the solid-phase lithium ion battery for operation management. This management method is direct and objective, and can be applied to most external environments.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

What is claimed is:

1. A method for early warning for a lithium battery, comprising:
establishing a three-dimensional (3D) electrochemical model for the lithium battery, and dividing the lithium battery into three portions respectively including a positive electrode, a negative electrode and a separator;
performing spatial discretization on the 3D electrochemical model according to a preset accuracy to establish the four-dimensional (4D) spatial coordinates of the lithium battery;
obtaining a current lithium ion concentration in each position of the lithium battery by simulation based on the 4D space coordinates, a historical lithium ion concentration and a historical diffusion coefficient in each position of the lithium battery; and
performing early warning for the lithium battery according to the current lithium ion concentration in each position, comprising: calculating state information of the lithium battery according to the current lithium ion concentration in each position, wherein the state information of the lithium battery includes one or more of a battery volumetric charge state, a battery surface charge state, an active particle volumetric charge state, and an active particle surface charge state,
wherein the battery volumetric charge state is
$$Bulk {SOC}^{\pm } = \frac{3}{{{L}^{\pm } ( {R}_{p}^{\pm } )}^{3}} {\int }_{0}^{{L}^{\pm }} {\int }_{0}^{{R}_{p}^{\pm }} {r}^{2} \frac{{c}^{\pm }}{{c}_{max}^{\pm }} dr dx$$
wherein Bulk SOC^{±} is the battery volumetric charge state, superscript “+” and “−” respectively represent the positive electrode and the negative electrode, L^{±} is a length of the positive electrode or the negative electrode,
$${R}_{p}^{\pm }$$
is a particle surface radius of an active material of the positive electrode or the negative electrode, r is a radius in a particle radius domain of the active material, c is a lithium ion concentration corresponding to a certain radius r in active material particles at a certain position of the x-axis, C^{±} is the lithium ion concentration on the surface of the active material particles at a certain position of the x-axis, and
$${c}_{max}^{\pm }$$
is a maximum volumetric lithium ion concentration that the active material particles can carry;
wherein the battery surface charge state is
$$Surface {SOC}^{\pm } = \frac{1}{{L}^{\pm }} {\int }_{0}^{{L}^{\pm }} \frac{{c}_{ss}^{\pm }}{{c}_{max}^{\pm }} dx$$
wherein Surface SOC^{±} is the battery surface charge state and
$${c}_{ss}^{\pm }$$
is solid surface concentration;
wherein the active particle volumetric charge state is
$$Particle {SOC}^{\pm } = \frac{3}{{( {R}_{p}^{\pm } )}^{3}} {\int }_{0}^{{R}_{p}^{\pm }} {r}^{2} \frac{{c}^{\pm }}{{c}_{max}^{\pm }} dr$$
wherein Particle SOC^{±} is the active particle volumetric charge state; and
wherein the active particle surface charge state is
$$Particle Surface {SOC}^{\pm } = \frac{{c}_{ss}^{\pm }}{{c}_{max}^{\pm }}$$
wherein Particle Surface SOC^{±} is the active particle surface charge state.

2. The method of claim 1, wherein said obtaining the current lithium ion concentration in each position of the lithium battery by simulation based on the 4D space coordinates, the historical lithium ion concentration and the historical diffusion coefficient in each position of the lithium battery comprises:
loading the solid-phase lithium ion concentration obtained by electric field decoupling at the immediately previous moment; and
based on a solid-phase lithium ion concentration governing equation, obtaining the solid-phase lithium ion concentration at the immediately next moment by a finite difference analysis, wherein the solid-phase lithium ion concentration governing equation comprises:
$$\frac{\partial {c}_{s}}{\partial t} ( x , y , z , r , t ) = \frac{1}{{r}^{2}} \frac{\partial }{\partial r} [ {D}_{s}^{\pm } {r}^{2} \frac{\partial {c}_{s}}{\partial r} ]$$
wherein Cₛ is the solid-phase lithium ion concentration, x, y, z are the 3D space coordinates, r is the radius dimension of x, y, z wincing; t is time;
$${D}_{s}^{\pm }$$
is a solid-phase mass transfer coefficient.

3. The method of claim 2, wherein said obtaining a current lithium ion concentration in each position of the lithium battery by simulation further comprises:
letting ζ=Cₛ·r, and changing
$$\frac{\partial {c}_{s}}{\partial t} ( x , y , z , r , t ) = \frac{1}{{r}^{2}} \frac{\partial }{\partial r} [ {D}_{s}^{\pm } {r}^{2} \frac{\partial {c}_{s}}{\partial r} ]$$
to:
$$\frac{\partial ζ}{\partial t} ( x , y , z , r , t ) = {D}_{s}^{\pm } \frac{\partial }{\partial r} [ \frac{\partial ζ}{\partial r} ] .$$

4. The method of claim 1, wherein said obtaining the current lithium ion concentration in each position of the lithium battery by simulation based on the 4D space coordinates, the historical lithium ion concentration and the historical diffusion coefficient in each position of the lithium battery comprises:
loading the liquid phase lithium ion concentration obtained by electric field decoupling at the immediately previous moment; and
based on an liquid phase lithium ion concentration governing equation, obtaining a liquid phase lithium ion concentration at the immediately next moment by a finite element method analysis, wherein the liquid-phase lithium ion concentration governing equation is:
$${ε}_{e}^{j} \frac{\partial {c}_{e}^{j}}{\partial t} ( x , y , z , t ) = {D}_{e} Δ {c}_{e}^{j} + {a}^{\pm } ( 1 - t ) {j}_{n}^{\pm } ( x , t )$$
wherein j represents the positive electrode, the negative electrode or the separator, Cₑ is the lithium ion concentration in the liquid phase, Dₑ is the mass transfer coefficient in the liquid phase, x, y, z are the 3D spatial coordinates, and t is the time.

5. The model of claim 1, wherein said performing early warning for the lithium battery according to the current lithium ion concentration in each position comprises:
based on the state information of the lithium battery, determining if operation of the lithium battery is cut off.

6. The method of claim 5, wherein said determining if the lithium battery is cut off based on the state information of the lithium battery comprises:
when the battery volume charge state is between a first threshold and a second threshold, cutting off the operation of the lithium battery.

7. The method of claim 5, wherein said determining if the lithium battery is cut off based on the state information of the lithium battery comprises:
when the battery surface charge state is between a third threshold and a fourth threshold, cutting off the operation of the lithium battery.

8. The method of claim 5, wherein said determining if the lithium battery is cut off based on the state information of the lithium battery comprises:
when the active particle volume charge state of the solid particles of the lithium battery exceeding a fifth threshold exceeds a first preset range, cutting off the operation of the lithium battery.

9. The method of claim 5, wherein said determining if the lithium battery is cut off based on the state information of the lithium battery comprises:
when the active particle volume charge state of the solid particles of the lithium battery exceeding a sixth threshold exceeds a second preset range, cutting off the operation of the lithium battery.
